(19) United States
(12) Patent Application Publication
(10) Pub. No.: US 2026/0323873 A1
(43) Pub. Date: Oct. 15, 2026

(54) AUTOMATIC LIQUID SUPPLY AND RECOVERY DEVICE

(71) Applicant: Foxconn Internet Advanced Technology (Shaoxing) Co., Ltd., Shaoxing (CN)

(72) Inventors: MING-YUAN WU, Shaoxing (CN); CHUN-YU SHIH, New Taipei (TW); ZHI-KUN DENG, Shaoxing (CN)

(21) Appl. No.: 19/630,827

(22) Filed: Mar. 27, 2026

(30) Foreign Application Priority Data
Apr. 9, 2025 (CN) 202520665195.5

(51) Int. Cl. H05K 7/20; G01F 15/12

(52) U.S. Cl. CPC H05K 7/20272; G01F 15/125; H05K 7/20763

(57) ABSTRACT

The present application provides an automatic liquid supply and recovery device including a liquid replenishment and recirculation assembly, a liquid recovery assembly, and a gas supply assembly. The liquid replenishment and recirculation assembly includes a first liquid storage tank, a replenishment pipeline, and a filling pipeline. The replenishment pipeline communicates between the first liquid storage tank and an external liquid source. The filling pipeline communicates between the first liquid storage tank and the inlet of the liquid cooling pipeline in the external device. The liquid recovery assembly includes a second liquid storage tank and an inlet pipeline. The inlet pipeline communicates between the second liquid storage tank and the outlet of the liquid cooling pipeline. The gas supply assembly includes an air compressor and an inlet gas pipeline. The inlet gas pipeline communicates between the air compressor and the inlet of the liquid cooling pipeline.

### FIELD

The subject matter relates to a liquid replenishment equipment, to an automatic liquid supply and recovery device.

### BACKGROUND

A server is a type of computer that provides computing or application services for other client devices on a network, such as PCs, smartphones, ATMs, and even large-scale equipment like train systems. With the rapid development of information and data technologies and their applications, traditional air cooling systems could no longer meet the demand.

Liquid cooling systems, by directly introducing coolant into servers, could significantly improve heat absorption and dissipation efficiency, ensuring stable operation of equipment. Market demand for the production capacity of liquid cooling systems is growing. However, traditional liquid cooling systems typically rely on manual liquid replenishment and recovery, which is inefficient, prone to errors, and unable to meet the requirements of modern industrial production.

Therefore, there is room for improvement in the art.

### BRIEF DESCRIPTION OF THE DRAWINGS

FIG. 1 is a schematic structural diagram of an automatic liquid supply and recovery device according to an embodiment of the present application;

FIG. 2 is a schematic diagram of liquid flow when an external liquid source supplies liquid to the automatic liquid supply and recovery device according to an embodiment of the present application;

FIG. 3 is a schematic diagram of liquid flow when the automatic liquid supply and recovery device circulates liquid to an external device according to an embodiment of the present application;

FIG. 4 is a schematic diagram of gas flow when the automatic liquid supply and recovery device recovers liquid from the external device according to an embodiment of the present application;

FIG. 5 is a schematic diagram of liquid flow when a second liquid storage tank of the automatic liquid supply and recovery device discharges liquid according to an embodiment of the present application.

### DETAILED DESCRIPTION

Implementations of the present technology will now be described, by way of example only, with reference to the attached figures.

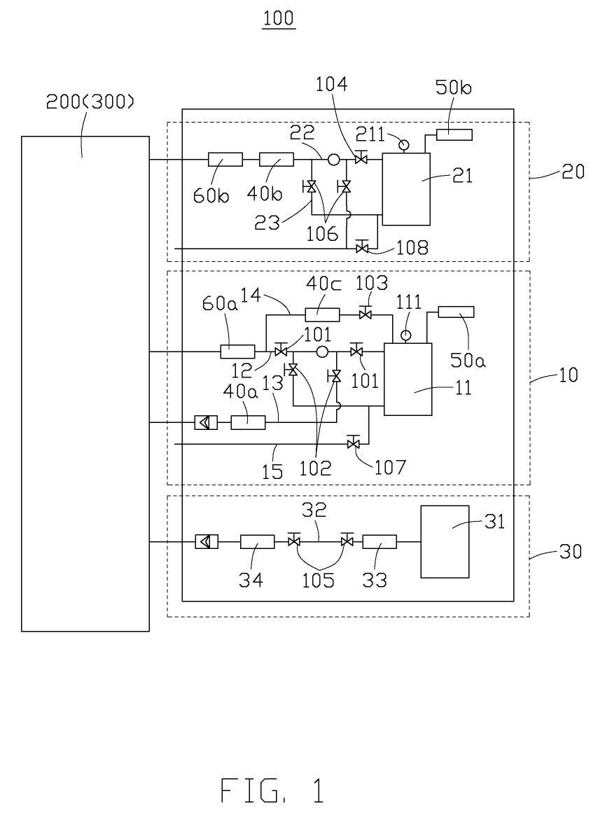

Please refer to FIG. 1, an embodiment of the present application provides an automatic liquid supply and recovery device 100. The automatic liquid supply and recovery device 100 is configured to supply liquid to a liquid cooling pipeline in an external device 200 and recover liquid from a liquid cooling pipeline in the external device 200. The external device 200 may be a server, which is not limited in the present application. The automatic liquid supply and recovery device 100 may also be communicated with an external liquid source 300.

Referring to FIGS. 1-3, in an embodiment, the automatic liquid supply and recovery device 100 includes a liquid replenishment and recirculation assembly 10, a liquid recovery assembly 20, and a gas supply assembly 30.

The liquid replenishment and recirculation assembly 10 includes a first liquid storage tank 11, a replenishment pipeline 12, and a filling pipeline 13. The replenishment pipeline 12 is configured to communicate with the first liquid storage tank 11 and the external liquid source 300. The external liquid source 300 is a liquid storage equipment such as a coolant storage device or cleaning solution storage device. Liquid in the external liquid source 300 could flow into the first liquid storage tank 11 via the replenishment pipeline 12.

The replenishment pipeline 12 is communicated with both the external liquid source 300 and the external device 200. For example, the replenishment pipeline 12 is communicated with the external liquid source 300 and the external device 200 through a two-way valve. The connection method between the replenishment pipeline 12 and the external device 200 is the same as the connection method between the replenishment pipeline 12 and the external device 200. To simplify the drawings, the external device 200 and the external liquid source 300 are shown as a single model in FIG. 1.

When it is necessary to replenish liquid in the first liquid storage tank 11 of the automatic liquid supply and recovery device 100, liquid from the external liquid source 300 flows into the first liquid storage tank 11 via the replenishment pipeline 12. The first liquid storage tank 11 is configured to storage liquid.

The replenishment pipeline 12 is used to replenish liquid from the external device 200 to the first liquid storage tank 11, which facilitates subsequent liquid filling operations of the automatic liquid supply and recovery device 100 on the external device 200.

In an embodiment, the filling pipeline 13 is configured to communicate with the first liquid storage tank 11 and the inlet of the liquid cooling pipeline in the external device 200, and liquid in the first liquid storage tank 11 could flow into the liquid cooling pipeline via the filling pipeline 13. When it is necessary to fill the external device 200 with liquid, the liquid in the first liquid storage tank 11 flows into the liquid cooling pipeline of the external device 200 via the filling pipeline 13.

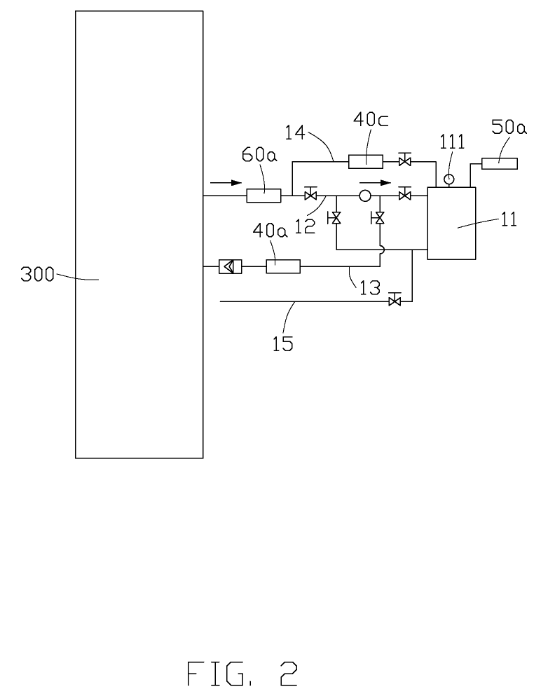

Referring to FIGS. 1 and 2, in an embodiment, the liquid recovery assembly 20 includes a second liquid storage tank 21 and an inlet pipeline 22. The inlet pipeline 22 is configured to communicate with the second liquid storage tank 21 and the outlet of the liquid cooling pipeline. Liquid in the liquid cooling pipeline could flow into the second liquid storage tank 21 via the inlet pipeline 22.

The gas supply assembly 30 includes an air compressor 31 and an inlet gas pipeline 32. The inlet gas pipeline 32 is configured to communicate with the air compressor 31 and the inlet of the liquid cooling pipeline. External air could be compressed by the air compressor 31 and flow into the liquid cooling pipeline via the inlet gas pipeline 32 to discharge the liquid in the liquid cooling pipeline.

When it is necessary to drain liquid from the external device 200, the air compressor 31 compresses external air and delivers the compressed air into the liquid cooling pipeline via the inlet gas pipeline 32. The liquid in the liquid cooling pipeline is discharged into the second liquid storage tank 21 via the inlet pipeline 22 with the action of the compressed air, thereby achieving recovery of the liquid from the external device 200 by the automatic liquid supply and recovery device 100.

Through the coordination of the liquid replenishment and recirculation assembly 10, the liquid recovery assembly 20, and the gas supply assembly 30, the automatic liquid supply and recovery device 100 can achieve automatic liquid replenishment and drainage recovery for the external device 200. Compared to traditional manual liquid replenishment and recovery, automatic liquid supply and recovery device 100 can not only improve liquid replenishment efficiency and accuracy, making it suitable for highly efficient automated production lines, but also reduce the labor intensity of workers and increase the efficiency of liquid replenishment and recovery.

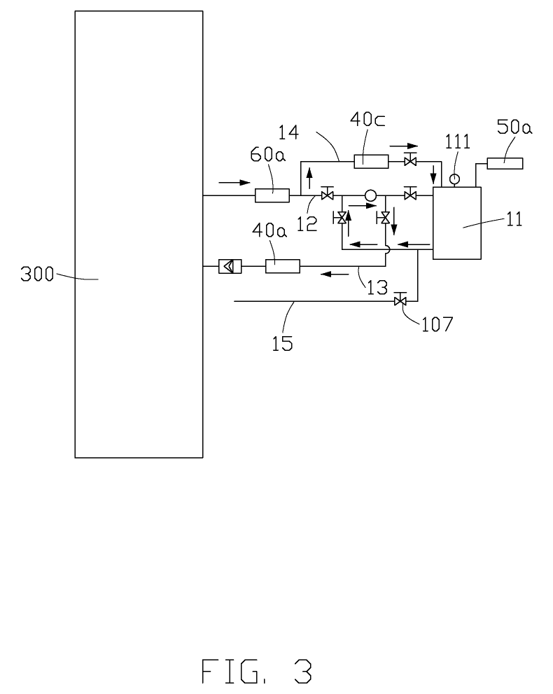

Referring to FIGS. 1 and 3, In an embodiment, the liquid replenishment and recirculation assembly 10 further includes a recirculation pipeline 14. The recirculation pipeline 14 is configured to communicate with the first liquid storage tank 11 and the outlet of the liquid cooling pipeline, and excess liquid in the liquid cooling pipeline could flow back into the first liquid storage tank 11 via the recirculation pipeline 14.

When the liquid in the first liquid storage tank 11 flows into the external device 200 via the filling pipeline 13 and excess liquid is generated due to saturation in the external device 200, the excess liquid could flow back into the first liquid storage tank 11 via the recirculation pipeline 14. For example, when the liquid cooling pipeline in the external device 200 is full and excess liquid is generated, the excess liquid flows back into the first liquid storage tank 11 via the recirculation pipeline 14. The liquid returning to the first liquid storage tank 11 could be reused by flowing into the external device 200 via the filling pipeline 13, which helps reduce liquid waste.

In another embodiment, the liquid in the first liquid storage tank 11 flows into the liquid cooling pipeline of the external device 200 via the filling pipeline 13, and after the external device 200 is filled, the excess liquid of the external device 200 flows back into the first liquid storage tank 11 via the recirculation pipeline 14. The liquid returning to the first liquid storage tank 11 continues to flow into the liquid cooling pipeline via the filling pipeline 13 until the liquid cooling pipeline in the external device 200 is completely filled.

Cyclic liquid replenishment for the external device 200 could be achieved by the recirculation pipeline 14, improving the completeness of liquid replenishment for the external device 200, reducing the risk of incomplete replenishment by the automatic liquid supply and recovery device 100, facilitating the cyclic use of liquid, reducing liquid waste, and lowering production costs.

Referring to FIG. 1, in an embodiment, the automatic liquid supply and recovery device 100 further includes a first flow meter 40a, a second flow meter 40b, and a third flow meter 40c. The first flow meter 40a is installed on the filling pipeline 13, the second flow meter 40b is installed on the inlet pipeline 22, and the third flow meter 40c is installed on the recirculation pipeline 14.

The first flow meter 40a is configured to monitor the liquid flow rate in the filling pipeline 13, the second flow meter 40b is configured to monitor the liquid flow rate in the inlet pipeline 22, and the third flow meter 40c is configured to monitor the liquid flow rate in the recirculation pipeline 14.

During the liquid filling process for the external device 200, the first flow meter 40a monitors the liquid flow rate in the filling pipeline 13 in real time. During the liquid drainage and recovery process for the external device 200, the second flow meter 40b monitors the liquid flow rate in the inlet pipeline 22 in real time, and the third flow meter 40c monitors the liquid flow rate in the recirculation pipeline 14 in real time.

When the flow meters, such as the first flow meter 40a, the second flow meter 40b, and the third flow meter 40c, detect an excessive liquid flow rate in the corresponding pipelines, such as the filling pipeline 13, the inlet pipeline 22, and the recirculation pipeline 14, the automatic liquid supply and recovery device 100 could reduce the flow velocity of the liquid in the corresponding pipeline; conversely, the automatic liquid supply and recovery device 100 could increase the flow velocity of the liquid in the corresponding pipeline.

For example, when the first flow meter 40a detects an excessive liquid flow rate in the corresponding filling pipeline 13, the automatic liquid supply and recovery device 100 could reduce the flow velocity of the liquid in filling pipeline 13.

Through the provision of the first flow meter 40a, the second flow meter 40b, and the third flow meter 40c, real-time monitoring of the liquid flow rate in the corresponding pipelines may be achieved. The automatic liquid supply and recovery device 100 is capable of automatically adjusting the liquid flow rate in the corresponding pipelines according to the monitoring results, so as to ensure that the liquid flow is maintained in a relatively balanced state. On the one hand, this helps to further improve the liquid replenishment precision of the automatic liquid supply and recovery device 100 and reduce the risk of excessive or insufficient liquid replenishment; on the other hand, this helps to enhance the stability and efficiency of liquid supply by the automatic liquid supply and recovery device 100.

The automatic liquid supply and recovery device 100 could automatically adjust the liquid flow in the corresponding pipelines, it helps reduce the risk of impact or pressure changes on the automatic liquid supply and recovery device 100 caused by improper control of liquid supply volume or excessively fast liquid replenishment speed, which accelerates equipment wear or damage. This is conducive to extending the service life of the automatic liquid supply and recovery device 100 and reducing subsequent maintenance costs.

Referring to FIG. 1, in an embodiment, the automatic liquid supply and recovery device 100 further includes a first liquid level sensor 50a, and the first liquid level sensor 50a is mounted on the first liquid storage tank 11. The first liquid level sensor 50a is configured to monitor the liquid level in the first liquid storage tank 11.

By configuring the first liquid level sensor 50a, real-time monitoring of the liquid level inside the first liquid storage tank 11 can be achieved. This facilitates timely replenishment of liquid into the first liquid storage tank 11, thereby improving the stability and safety of liquid replenishment for the automatic liquid supply and recovery device 100.

The automatic liquid supply and recovery device 100 further includes a second liquid level sensor 50b. The second liquid level sensor 50b is installed on the second liquid storage tank 21. The second liquid level sensor 50b is configured to monitor the liquid level inside the second liquid storage tank 21.

By configuring the second liquid level sensor 50b, real-time monitoring of the liquid level inside the second liquid storage tank 21 can be achieved. This is beneficial for promptly stopping the recovery of liquid from the external device 200 into the second liquid storage tank 21 when it is full or reaches a set capacity, or for timely draining of excess liquid from the second liquid storage tank 21. Furthermore, it facilitates the real-time replenishment of liquid into the second liquid storage tank 21, thereby enhancing the stability and safety of liquid replenishment for the automatic liquid supply and recovery device 100.

Referring to FIGS. 1, 2, and 4, in an embodiment, the automatic liquid supply and recovery device 100 further includes a first liquid filter 60a and a second liquid filter 60b. The first liquid filter 60a is installed on the replenishment pipeline 12, and the second liquid filter 60b is installed on the inlet pipeline 22. The first liquid filter 60a is configured to filter liquid flowing via the replenishment pipeline 12, and the second liquid filter 60b is configured to filter liquid flowing via the inlet pipeline 22.

The first liquid filter 60a and the second liquid filter 60b can effectively block and filter impurities in the liquid, thereby ensuring the cleanliness of the liquid entering the liquid cooling pipe, and further guaranteeing the normal operation and performance of the external device 200.

In an embodiment, both the first liquid filter 60a and the second liquid filter 60b are reverse osmosis filters. The reverse osmosis filter comprises a semipermeable membrane, for example, the pore size of the semipermeable membrane is approximately 0.0001 microns, and the semipermeable membrane allows water molecules to pass through while retaining impurities such as heavy metals, viruses, bacteria, and inorganic salts.

In another embodiment, the first liquid filter 60a and the second liquid filter 60b can also be other filter structures such as activated carbon filters, ceramic filters, or filter membranes. The first liquid filter 60a and the second liquid filter 60b can be the same or different.

Referring to FIG. 1, in an embodiment, the first liquid storage tank 11 is provided with a first pressure relief valve 111. The first pressure relief valve 111 is configured to discharge gas from inside the first liquid storage tank 11 when liquid from the external liquid source 300 flows into the first liquid storage tank 11 via the replenishment pipeline 12.

The second liquid storage tank 21 is provided with a second pressure relief valve 211. The second pressure relief valve 211 is configured to discharge gas from inside the second liquid storage tank 21 when liquid from the liquid cooling pipeline flows into the second liquid storage tank 21 via the inlet pipeline 22.

The first pressure relief valve 111 and the second pressure relief valve 211 facilitate the automatic discharge of excess gas from the first liquid storage tank 11 and the second liquid storage tank 21 respectively, so as to ensure that the pressure in the first liquid storage tank 11 and the pressure in the second liquid storage tank 21 are maintained within a safe range, thereby further improving the operational safety of the automatic liquid supply and recovery device 100.

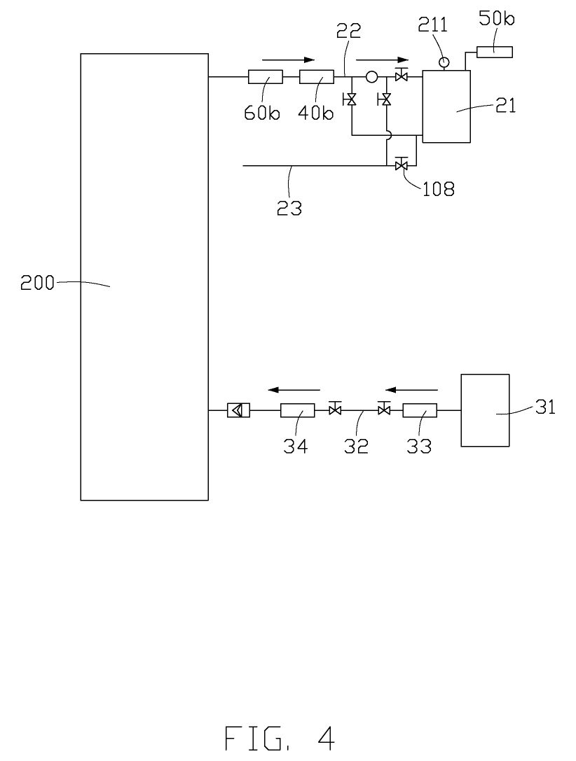

Referring to FIGS. 1 and 4, in an embodiment, the gas supply assembly 30 further includes a gas filter 33. The gas filter 33 is installed on the inlet gas pipeline 32. The gas filter 33 is configured to filter moisture and impurities from the compressed air, ensuring gas quality, and thereby protecting the liquid cooling pipeline from corrosion and damage.

In an embodiment, the gas filter 33 is an adsorption dryer. In another embodiment, the gas filter 33 is another filter structure designed according to the actual situation.

In an embodiment, the gas supply assembly 30 further includes a pressure sensor 34. The pressure sensor 34 is installed on the inlet gas pipeline 32. The pressure sensor 34 is configured to monitor pressure changes within the inlet gas pipeline 32, reducing the risk of damage to the inlet gas pipeline 32 due to excessive pressure, and further improving the operational safety of the automatic liquid supply and recovery device 100 and lowering production costs.

For example, when the pressure in the inlet gas pipeline 32 is too high, the automatic liquid supply and recovery device 100 can reduce the rate at which the air compressor 31 delivers compressed gas; when the pressure in the inlet gas pipeline 32 is too low, the automatic liquid supply and recovery device 100 can increase the rate at which the air compressor 31 delivers compressed gas.

Monitoring pressure changes in the inlet gas pipeline 32 with the pressure sensor 34 also helps detect potential blockages or leaks in the pipelines of the automatic liquid supply and recovery device 100. For example, a sudden increase in pressure in the inlet gas pipeline 32 may indicate a potential blockage, while a sudden drop in pressure may indicate a potential leak or rupture in the inlet gas pipeline 32.

Referring to FIG. 1, in an embodiment, the liquid replenishment and recirculation assembly 10 further includes a first outlet pipeline 15. The first outlet pipeline 15 is configured to communicate with the first liquid storage tank 11, allowing liquid inside the first liquid storage tank 11 to flow out via the first outlet pipeline 15, remaining liquid in the first liquid storage tank 11 can be drained, facilitating subsequent maintenance or replacement of the first liquid storage tank 11.

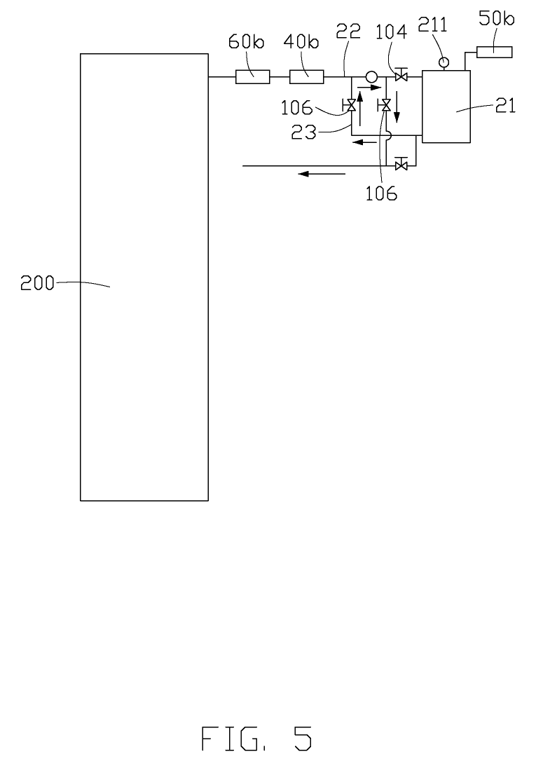

Referring to FIGS. 1 and 5, in an embodiment, the liquid recovery assembly 20 further includes a second outlet pipeline 23. The second outlet pipeline 23 is configured to communicate with the second liquid storage tank 21, allowing liquid inside the second liquid storage tank 21 to flow out via the second outlet pipeline 23, remaining liquid in the second liquid storage tank 21 can be drained, facilitating subsequent maintenance or replacement of the second liquid storage tank 21.

The automatic liquid supply and recovery device 100 further includes a first solenoid valve 101, a second solenoid valve 102, and a third solenoid valve 103. The first solenoid valve 101 is installed on the replenishment pipeline 12, the second solenoid valve 102 is installed on the filling pipeline 13, and the third solenoid valve 103 is installed on the recirculation pipeline 14. When replenishing the first liquid storage tank 11 of the automatic liquid supply and recovery device 100, the third solenoid valve 103 on the recirculation pipeline 14 and the second solenoid valve 102 on the filling pipeline 13 are both in closed state. The first solenoid valve 101 on the replenishment pipeline 12 is in open state. The external liquid source 300 injects liquid into the first liquid storage tank 11 via the replenishment pipeline 12.

When filling the external device 200, the third solenoid valve 103 on the recirculation pipeline 14 and the second solenoid valve 102 on the filling pipeline 13 are both in open state. The first solenoid valve 101 on the replenishment pipeline 12 is in closed state. Liquid from the first liquid storage tank 11 flows via the filling pipeline 13 and enters the liquid cooling pipeline of the external device 200.

Excess liquid in the liquid cooling pipeline can flow back to the first liquid storage tank 11 via the recirculation pipeline 14. The liquid returning to the first liquid storage tank 11 continues to flow into the liquid cooling pipeline via the filling pipeline 13, until the liquid cooling pipeline in the external device 200 is completely filled.

The automatic liquid supply and recovery device 100 further includes a fourth solenoid valve 104 and a fifth solenoid valve 105. The fourth solenoid valve 104 is installed on the inlet pipeline 22, and the fifth solenoid valve 105 is installed on the inlet gas pipeline 32.

When draining liquid from the external device 200, the third solenoid valve 103 on the recirculation pipeline 14, the second solenoid valve 102 on the filling pipeline 13, and the first solenoid valve 101 on the replenishment pipeline 12 are all in closed state. The fifth solenoid valve 105 on the inlet gas pipeline 32 and the fourth solenoid valve 104 on the inlet pipeline 22 are both in open state. The air compressor 31 compresses external air and delivers the compressed air to the liquid cooling pipeline via the inlet gas pipeline 32. The liquid in the liquid cooling pipeline is forced out via the inlet pipeline 22 into the second liquid storage tank 21 with the pressure of the compressed air.

The automatic liquid supply and recovery device 100 further includes a sixth solenoid valve 106. The sixth solenoid valve 106 is installed on the second outlet pipeline 23. When draining the remaining liquid from the second liquid storage tank 21, the sixth solenoid valve 106 is opened and the fourth solenoid valve 104 is closed.

The automatic liquid supply and recovery device 100 further includes a first manual valve 107. The first manual valve 107 is arranged on first outlet pipeline 15 for manual operation. In the event of equipment failure or power outage, the liquid in first liquid storage tank 11 can be discharged by manually operating the first manual valve 107, facilitating the maintenance of the first liquid storage tank 11.

The automatic liquid supply and recovery device 100 further includes a second manual valve 108. The second manual valve 108 is installed on the second outlet pipeline 23 for manual operation. In the event of equipment failure or power outage, the liquid in second liquid storage tank 21 can be discharged by manually operating the second manual valve 108, facilitating the maintenance of the second liquid storage tank 21.

The terms used in the present application, such as “first” and “second”, do not intended to indicate any order, quantity, or importance of related components, but are only used for differentiation between the related components.

As used in the present application, the term “a” or “one” do not intended to limit the quantity of the related object, but to indicate the existence of at least one related object.

In the present application, the terms indicating direction or position, such as “top”, “bottom”, “side”, “longitudinal”, “transverse”, “middle”, “center, “outer”, “inner”, “horizontal”, “vertical”, “left”, “right”, “upper”, and “lower”, refers to a relative position rather than an absolute position.

The terms used in the present application, such as “substantially”, “whole”, “approximate”, and “similar”, are intended to indicate that the object has related characteristics but allow for certain deviations. The deviation may depend on a specific background. For example, the dimension of deviation may depend on a specific background, comprising but not limited to national standards for dimensional tolerances.

What is claimed is:

1. An automatic liquid supply and recovery device, comprising:
a liquid replenishment and recirculation assembly, comprising:
a first liquid storage tank,
a replenishment pipeline communicating with the first liquid storage tank, configured for communicating with an external liquid source and flowing liquid from the external liquid source into the first liquid storage tank via the replenishment pipeline, and
a filling pipeline communicating with the first liquid storage tank, configured for communicating with an inlet of a liquid cooling pipeline in an external device and flowing liquid from the first liquid storage tank into the liquid cooling pipeline via the filling pipeline;
a liquid recovery assembly, comprising:
a second liquid storage tank,
an inlet pipeline communicating with the second liquid storage tank, configured for communicating with an outlet of the liquid cooling pipeline and flowing liquid from the liquid cooling pipeline into the second liquid storage tank via the inlet pipeline; and
a gas supply assembly, comprising:
an air compressor, and
an inlet gas pipeline communicating with the air compressor, configured for communicating with the inlet of the liquid cooling pipeline, flowing external air compressed by the air compressor into the liquid cooling pipeline via the inlet gas pipeline, and discharging liquid from the liquid cooling pipeline.

2. The automatic liquid supply and recovery device to claim 1, further comprising:
a first flow meter arranged on the filling pipeline,
a second flow meter arranged on the inlet pipeline;
wherein the first flow meter is configured to monitor a liquid flow in the filling pipeline, and the second flow meter is configured to monitor a liquid flow in the inlet pipeline.

3. The automatic liquid supply and recovery device to claim 1, wherein the liquid replenishment and recirculation assembly further comprises a recirculation pipeline communicating with the first liquid storage tank, configured for communicating with the outlet of the liquid cooling pipeline and flowing excess liquid in the liquid cooling pipeline to the first liquid storage tank via the recirculation pipeline.

4. The automatic liquid supply and recovery device to claim 3, further comprising a third flow meter configured to monitor a liquid flow in the recirculation pipeline.

5. The automatic liquid supply and recovery device to claim 3, wherein the liquid recovery assembly further comprises a second outlet pipeline communicating with the second liquid storage tank, and configured for discharging liquid in the second liquid storage tank via the second outlet pipeline.

6. The automatic liquid supply and recovery device to claim 5, further comprising:
a first solenoid valve arranged on the replenishment pipeline,
a second solenoid valve arranged on the filling pipeline, and
a third solenoid valve arranged on the recirculation pipeline;
wherein, in a case that the third solenoid valve and the second solenoid valve are closed, and the first solenoid valve is open; the first liquid storage tank is replenished by liquid flowing from the external liquid source into the first liquid storage tank via the replenishment pipeline.

7. The automatic liquid supply and recovery device to claim 6, further comprising:
a fourth solenoid valve arranged on the inlet pipeline, and
a fifth solenoid valve arranged on the inlet gas pipeline;
wherein, in a case that the third solenoid valve, the second solenoid valve, and the first solenoid valve are closed, and the fifth solenoid valve and the fourth solenoid valve are open, the automatic liquid supply and recovery device causes the external device to drain.

8. The automatic liquid supply and recovery device to claim 7, further comprising a sixth solenoid valve arranged on the second outlet pipeline;
wherein, in a case that the sixth solenoid valve is open, and the fourth solenoid valve is closed, the second liquid storage tank discharges residual liquid.

9. The automatic liquid supply and recovery device to claim 1, further comprising:
a first liquid level sensor arranged on the first liquid storage tank, and
a second liquid level sensor arranged on the second liquid storage tank;
wherein the first liquid level sensor monitors a liquid level in the first liquid storage tank, and the second liquid level sensor monitors a liquid level in the second liquid storage tank.

10. The automatic liquid supply and recovery device to claim 1, further comprising:
a first liquid filter arranged on the replenishment pipeline, and
a second liquid filter arranged on the inlet pipeline;
wherein the first liquid filter filters liquid in the replenishment pipeline, and the second liquid filter filters liquid in the inlet pipeline.

11. The automatic liquid supply and recovery device to claim 1, wherein the first liquid storage tank comprises a first pressure relief valve configured to vent gas in first liquid storage tank during liquid flowing from the external liquid source into the first liquid storage via the replenishment pipeline;
the second liquid storage tank comprises a second pressure relief valve configured to vent gas in the second liquid storage tank during liquid flowing from the liquid cooling pipeline into the second liquid storage via the inlet pipeline.

12. The automatic liquid supply and recovery device to claim 1, wherein the gas supply assembly further comprises a gas filter arranged on the inlet gas pipeline, the gas filter is configured to remove moisture and impurities from the air compressed by the air compressor.

13. The automatic liquid supply and recovery device to claim 12, wherein the gas supply assembly further comprises a pressure sensor arranged on the inlet gas pipeline, the pressure sensor is configured to monitor pressure variations within the inlet gas pipeline.

14. The automatic liquid supply and recovery device to claim 1, wherein the liquid replenishment and recirculation assembly further comprises a first outlet pipeline communicating with the first liquid storage tank and configured for discharging liquid from the first liquid storage tank.

15. The automatic liquid supply and recovery device to claim 14, further comprising:
a first manual valve arranged on the first outlet pipeline.

16. The automatic liquid supply and recovery device to claim 1, wherein the liquid recovery assembly further comprises a second outlet pipeline communicating with the second liquid storage tank and configured for discharging liquid from the second liquid storage tank.

17. The automatic liquid supply and recovery device to claim 16, further comprising:
a second manual valve arranged on the second outlet pipeline.

18. An automatic liquid supply and recovery device, comprising:
a liquid replenishment and recirculation assembly, comprising:
a first liquid storage tank,
a replenishment pipeline communicating the first liquid storage tank, configured for communicating with an external liquid source and flowing liquid from the external liquid source into the first liquid storage tank via the replenishment pipeline, and
a filling pipeline communicating with the first liquid storage tank, configured for communicating with an inlet of a liquid cooling pipeline in an external device, and flowing liquid from the first liquid storage tank into the liquid cooling pipeline via the filling pipeline;
a liquid recovery assembly, comprising:
a second liquid storage tank,
an inlet pipeline communicating with the second liquid storage tank, configured for communicating with an outlet of the liquid cooling pipeline and flowing liquid from the liquid cooling pipeline into the second liquid storage tank via the inlet pipeline.

19. The automatic liquid supply and recovery device to claim 18, wherein the liquid replenishment and recirculation assembly further comprises a recirculation pipeline communicating with the first liquid storage tank, configured for communicating with the outlet of the liquid cooling pipeline, and flowing excess liquid in the liquid cooling pipeline to the first liquid storage tank via the recirculation pipeline.

20. The automatic liquid supply and recovery device to claim 18, further comprising:
a first liquid level sensor arranged on the first liquid storage tank, and
a second liquid level sensor arranged on the second liquid storage tank;
wherein the first liquid level sensor monitors a liquid level in the first liquid storage tank, and the second liquid level sensor monitors a liquid level in the second liquid storage tank.
